(19) United States
(12) Patent Application Publication
(10) Pub. No.: US 2012/0061723 A1
(43) Pub. Date: Mar. 15, 2012

(54) SEMICONDUCTOR DEVICE

(75) Inventor: Takaaki ISHII, Hyogo-ken (JP)

(73) Assignee: Kabushiki Kaisha Toshiba, Tokyo (JP)

(21) Appl. No.: 13/231,829

(22) Filed: Sep. 13, 2011

(30) Foreign Application Priority Data
Sep. 14, 2010 (JP) 2010-205481

(51) Int. Cl. H01L 29/739

(52) U.S. Cl. 257/139; 257/E29.198

(57) ABSTRACT

According to one embodiment, a semiconductor device includes a first conductivity type base layer, a second conductivity type base layer, a gate insulating film, a first conductivity type source layer, a gate electrode, and a main electrode. The gate electrode is provided inside of the gate insulating film in the trench. The main electrode is provided on the surface of the second conductivity type base layer and on a surface of the first conductivity type source layer. The main electrode is provided at a position deeper than the gate electrode and the second conductivity type base layer in the trench. The main electrode is electrically connected to the second conductivity type base layer and the first conductivity type source layer.

### CROSS-REFERENCE TO RELATED APPLICATION

This application is based upon and claims the benefit of priority from Japanese Patent Application No.2010-205481, filed on Sep. 14, 2010; the entire contents of which are incorporated herein by reference.

### FIELD

Embodiments described herein relate generally to a semiconductor device.

### BACKGROUND

In a vertical Insulated Gate Bipolar Transistor (IGBT) having a trench-gate structure, when a positive bias to an emitter electrode is applied to a gate electrode, an inversion layer is formed in the vicinity of the boundary with a gate insulating film in a P-type base layer, and electrons are injected into an N-type base layer. Then, holes are injected from the collector side into the N-type base layer, whereby an ON state is generated. The injected holes flow into the P-type base layer through the N-type base layer. In such a structure, if a region such as a floating P-type semiconductor layer in which holes do not flow is formed, an effect that holes are accumulated on the emitter electrode side in the N-type base layer, and injection of electrons is promoted has been reported.

### BRIEF DESCRIPTION OF THE DRAWINGS

FIG. 1 is a schematic cross-sectional view of a semiconductor device of a first embodiment;

FIG. 2 is a schematic plan view of the semiconductor device of the first embodiment;

FIGS. 3A to 5D are schematic cross-sectional views illustrating a method for manufacturing the semiconductor device of the first embodiment;

FIG. 6 is a schematic cross-sectional view of a semiconductor device of a second embodiment;

FIG. 7 is an A-A sectional diagram in FIG. 6;

FIGS. 8A to 9D are schematic cross-sectional views illustrating a method for manufacturing the semiconductor device of the second embodiment;

FIG. 10 is a schematic cross-sectional view of a semiconductor device of a third embodiment;

FIG. 11 is a schematic cross-sectional view of a semiconductor device of a fourth embodiment; and

FIG. 12 is a schematic cross-sectional view of a semiconductor device of a fifth embodiment.

### DETAILED DESCRIPTION

According to one embodiment, a semiconductor device includes a first conductivity type base layer, a second conductivity type base layer, a gate insulating film, a first conductivity type source layer, a gate electrode, and a main electrode. The second conductivity type base layer is provided on the first conductivity type base layer. The gate insulating film is provided on a side wall of each of a plurality of trenches which reach the first conductivity type base layer from a surface of the second conductivity type base layer. The first conductivity type source layer is selectively provided on the surface of the second conductivity type base layer adjacently to the gate insulating film. The gate electrode is provided inside of the gate insulating film in the trench. The main electrode is provided on the surface of the second conductivity type base layer and on a surface of the first conductivity type source layer. The main electrode is provided at a position deeper than the gate electrode and the second conductivity type base layer in the trench. The main electrode is electrically connected to the second conductivity type base layer and the first conductivity type source layer.

Embodiments will be described below referring to the attached drawings. In each figure, the same reference numerals are given to the same elements. In the following embodiment, a first conductivity type is referred to as an N-type and a second conductivity type as a P-type, respectively, but the first conductivity type may be the P-type and the second conductivity type may the N type. Also, silicon is used as a semiconductor. Alternatively, semiconductors other than silicon (compound semiconductors such as SiC, GaN and the like) may be used.

The semiconductor device according to the embodiment is a vertical device in which a current path is formed in a vertical direction which connects a first main electrode provided on one of the major surface sides in a semiconductor layer (or a substrate) and a second main electrode provided on the other major surface side to each other. In the following embodiments, an Insulated Gate Bipolar Transistor (IGBT) is cited as an example of the semiconductor devices, but it may be a Metal-Oxide-Semiconductor Field Effect Transistor (MOSFET). In the case of MOSFET, it is necessary that a P⁺-type collector layer 11, which will be described below, is replaced by an N⁺-type drain layer.

### First Embodiment

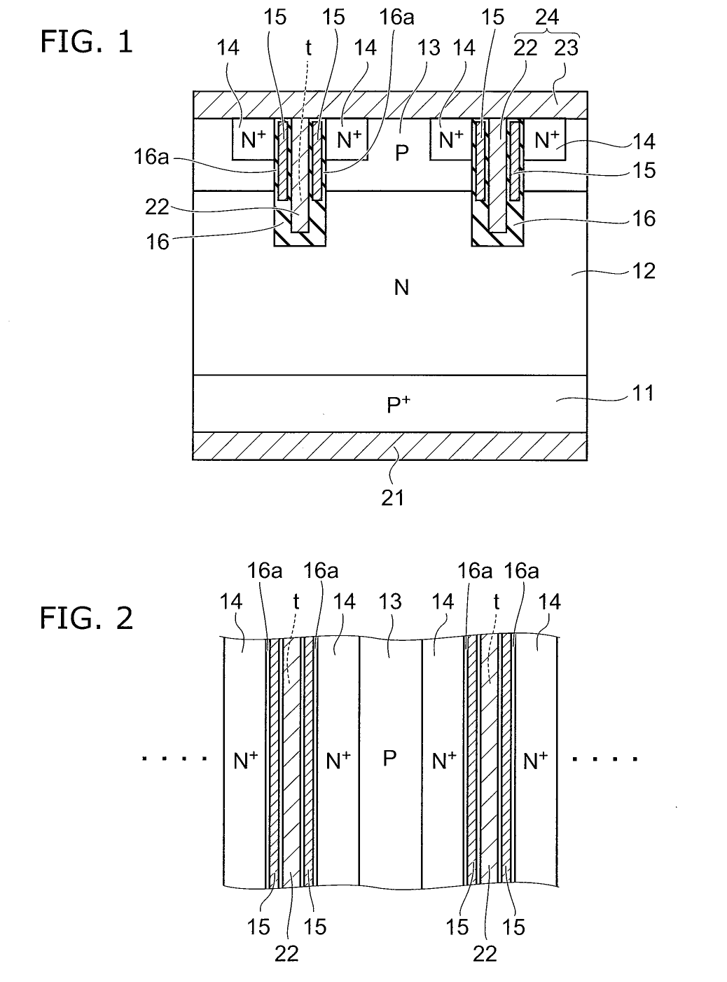

FIG. 1 is a schematic sectional diagram of a semiconductor device of a first embodiment.

FIG. 2 is a schematic diagram exemplifying a plan layout on the emitter side in the semiconductor device.

A semiconductor layer includes a P⁺-type collector layer 11, an N-type base layer 12, a P-type base layer 13, and an N⁺-type source layer 14. The collector layer 11 has P-type impurity concentration higher than that of the P-type base layer 13. The source layer 14 has N-type impurity concentration higher than that of the N-type base layer 12.

The N-type base layer 12 is provided on the collector layer 11. The P-type base layer 13 is provided on the N-type base layer 12. The source layer 14 is selectively provided on the surface of the P-type base layer 13.

On the surface sides of those semiconductor layers, a plurality of trenches t are formed. Each of the tranches t reaches the N-type base layer 12 from the surface of the P-type base layer 13. That is, the trench t penetrates the p-type base layer 13 and the bottom part of the trench t is located within the N-type base layer 12.

On the side wall and the bottom part of the trench t, an insulating film 16 is provided. The insulating film in the insulating film 16 provided particularly on the side wall of the trench t is referred to as a gate insulating film 16a.

The source layer 14 is adjacent to the side wall of the trench t. That is, the source layer 14 is adjacent to the gate insulating film 16a. Adjacent to the both sides in the width direction of one trench t, a pair of the source layers 14 are provided.

In the trench t, a gate electrode 15 is provided. The gate electrode 15 is provided inside the gate insulating film 16a in the trench t. In one trench t, a pair of the gate electrodes 15 separated in the width direction of the trench t are provided. The bottom parts of the gate electrodes 15 are located at positions deeper than the P-type base layer 13 and close to the boundary surface (PN-junction surface) between the P-type base layer 13 and the N-type base layer 12. The gate electrodes 15 oppose the p-type base layer 13 through the gate insulating film 16a.

On the surface in the collector layer 11 on the side opposite to the surface on which the N-type base layer 12 is provided, a collector electrode 21 is provided. The collector layer 11 forms ohmic-contact with the collector electrode 21 and is electrically connected to the collector electrode 21.

On the surface of the P-type base layer 13 and on the surface of the source layer 14, an emitter electrode 24 is provided. The emitter electrode 24 is electrically connected to the source layer 14 and the P-type base layer 13. The emitter electrode 24 has a surface electrode 23 and an buried electrode 22.

The surface electrode 23 is provided on the surface of the P-type base layer 13 and on the surface of the source layer 14. The surface electrode 23 forms ohmic-contact with the surface of the source layer 14 and is electrically connected to the source layer 14. The surface in the P-type base layer 13 in contact with the surface electrode 23 has relatively high P-type impurity concentration, and the surface electrode 23 forms ohmic-contact with the surface. Therefore, the P-type base layer 13 is also electrically connected with the surface electrode 23.

The surface electrode 23 is also provided on the trench t. In the trench t, the buried electrode 22 is provided under the surface electrode 23. The buried electrode 22 is provided between the pair of gate electrodes 15 in the trench t. An upper end portion of the buried electrode 22 continues to the surface electrode 23. The buried electrode 22 extends in the depth direction in the trench t from the surface electrode 23 to a position deeper than the gate electrode 15. The bottom part of the buried electrode 22 is located at a position deeper than the bottom parts of the P-type base layer 13 and the gate electrode 15.

The gate electrode 15 and the buried electrode 22 are provided in one trench t. The insulating film 16 is provided between the buried electrode 22 and the gate electrode 15. The insulating film 16 is provided also between the gate electrode 15 and the surface electrode 23. The insulating film 16 is provided also under the gate electrode 15 and under the buried electrode 22 in the trench t.

As illustrated in FIG. 2, the source layer 14, the trench t, the gate electrode 15, and the buried electrode 22 are formed by a stripe-shaped plan pattern, for example.

A part of the gate electrode 15 is led upward and connected to gate interconnect, not shown. On plan view of FIG. 2, for example, an end portion in the longitudinal direction of the gate electrode 15 is led upward and connected to the gate interconnect.

The collector electrode 21 and the surface electrode 23 are made of a metal material, for example. The buried electrode 22 and the gate electrode 15 are made of a semiconductor material to which impurities are added and having conductivity (polycrystalline silicon, for example). Alternatively, metal may be used as the buried electrode 22 and the gate electrode 15.

Relatively speaking, in a state in which a high potential is applied to the collector electrode 21 and a low potential to the emitter electrode 24, when a desired gate potential is applied to the gate electrode 15, an inversion layer (channel) is formed in the vicinity of the boundary with the gate insulating film 16a in the P-type base layer 13. For example, a positive potential to an emitter potential at a ground potential or a negative potential is applied to the gate electrode 15. A positive potential higher than the gate potential is applied to the collector electrode 21.

As a result, electrons are injected from the source layer 14 to the N-type base layer 12 through the channel, whereby the ON state is generated. At this time, holes are further injected into the N-type base layer 12 from the collector layer 11. The electrons injected into the N-type base layer 12 flow into the collector electrode 21 through the collector layer 11. The holes injected into the N-type base layer 12 flow into the surface electrode 23 through the P-type base layer 13. In IGBT, in the ON state, holes are injected from the collector layer 11 to the N-type base layer 12, which causes conductivity modulation, and resistance of the N-type base layer 12 is reduced.

In the embodiment, the buried electrode 22, which is a part of the emitter electrode 24 and to which the emitter potential is given, is located at a position lower than the gate electrode 15 in the trench t. That is, a part of the emitter electrode 24 is located closer to the collector electrode 21 side than the gate electrode 15.

Therefore, a gate-collector capacity can be reduced, and controllability of the gate potential, that is, switching controllability is improved. Specifically, a drop in a switching speed caused by the gate-collector capacity can be suppressed. Also, current capacity of a gate driving circuit can be reduced.

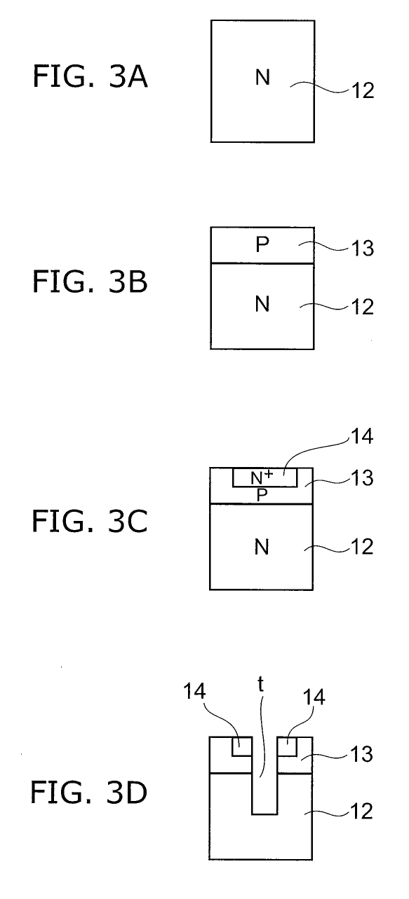

Subsequently, by referring to FIGS. 3A to 5D, a manufacturing method of the semiconductor device of the embodiment will be described.

After the N-type base layer 12 is formed (FIG. 3A), the P-type base layer 13 is formed on the surface side of the N-type base layer 12 (FIG. 3B). Moreover, the source layer 14 is formed on the surface of the P-type base layer 13 (FIG. 3C).

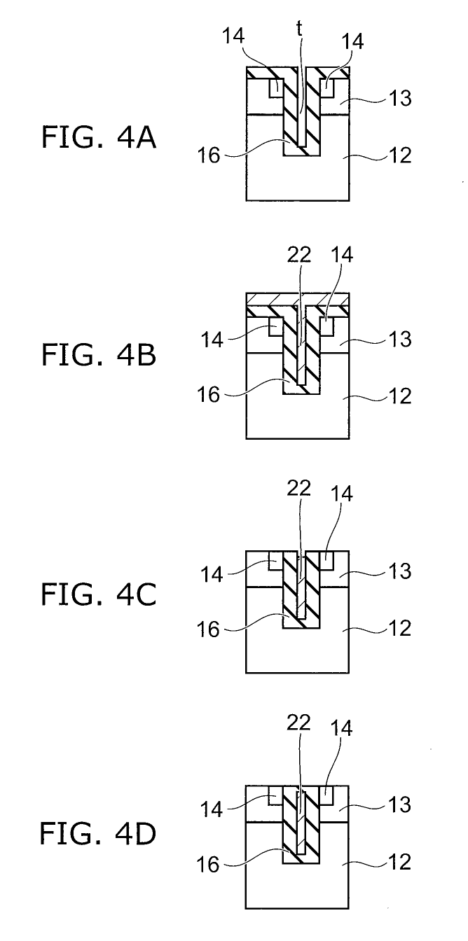

After that, as illustrated in FIG. 3D, the trench t reaching the N-type base layer 12 from the surface of the source layer 14 is formed. After the trench t is formed, as illustrated in FIG. 4A, the insulating film 16 is formed on the side walls and the bottom part of the trench t. Inside the insulating film 16, a cavity is formed. Then, the buried electrode 22 is buried in the cavity (FIG. 4B). It may be so configured that the P-type base layer 13 and the source layer 14 may be formed after the trench t is formed in advance.

After that, the insulating film and the electrode material on the surface of the semiconductor layer are removed (FIG. 4C), and the top face of the buried electrode 22 is covered with the insulating film 16 (FIG. 4D).

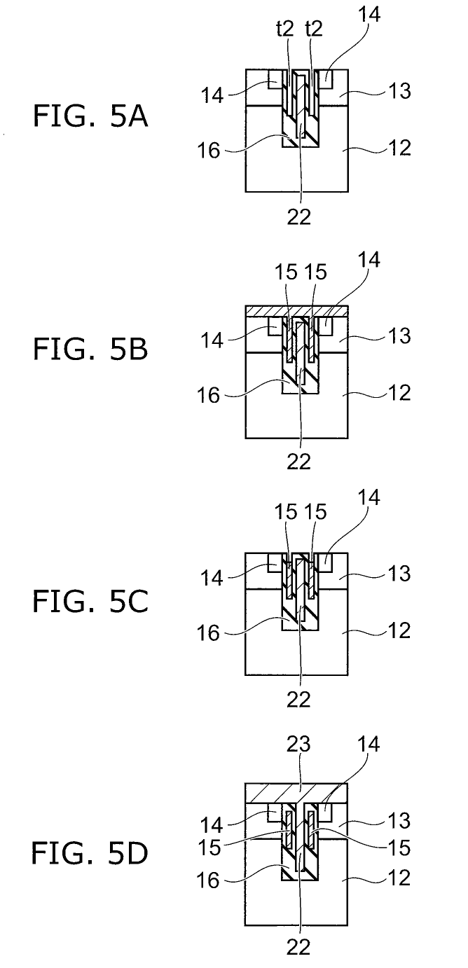

After that, as illustrated in FIG. 5A, a second trench t2 is formed in the insulating film 16 between the side wall of the trench t and the buried electrode 22, and the gate electrode 15 is embedded in the second trench t2 (FIG. 5B). The second trench t2 is narrower and shallower than the trench t.

After that, as illustrated in FIGS. 5C to 5D, the gate electrode material on the surface of the semiconductor layer is removed, the insulating film 16 is formed on the gate electrode 15, and the top face of the buried electrode 22 is exposed. Then, the surface electrode 23 of the emitter electrode is formed on the surface of the source layer 14, on the surface of the P-type base layer 13 and on the surface of the buried electrode 22.

### Second Embodiment

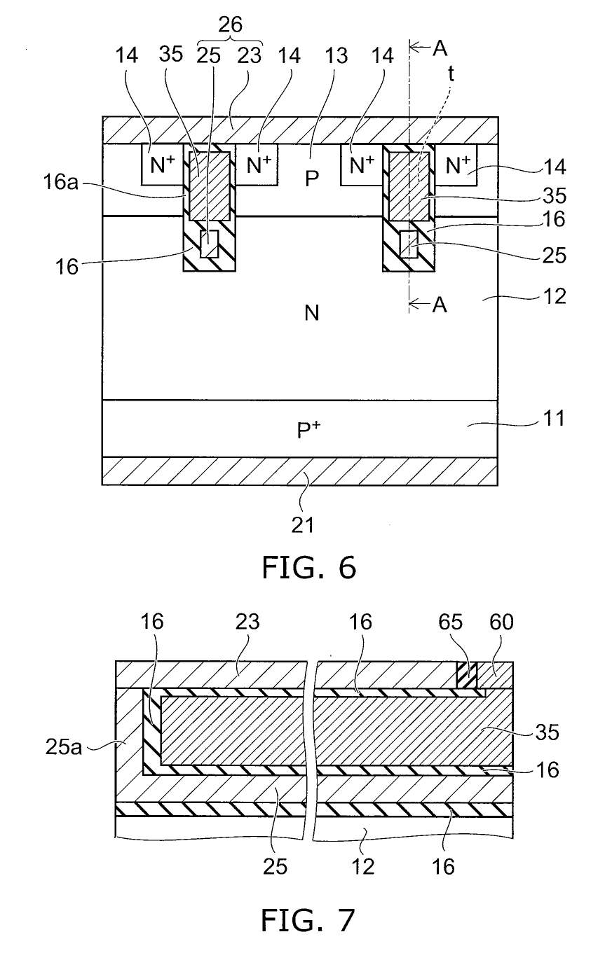

FIG. 6 is a schematic sectional diagram of a semiconductor device of a second embodiment.

FIG. 7 is an A-A sectional diagram in FIG. 6.

In the embodiment, too, the trench t penetrates the P-type base layer 13, and the bottom part of the trench t is located in the N-type base layer 12. On the side walls and the bottom part of the trench t, the insulating film 16 is provided. A pair of the source layers 14 adjoin the gate insulating film 16a sandwiching the trench t between them.

The embodiment is different from the first embodiment in the structure inside the trench t.

In the trench t, the gate electrode 35 is provided. The gate electrode 35 is provided inside the gate insulating film 16a in the trench t. The bottom part of the gate electrode 35 is located at a position deeper than that of the P-type base layer 13 and located in the vicinity of the boundary surface (PN-junction surface) between the P-type base layer 13 and the N-type base layer 12. The gate electrode 35 opposes the P-type base layer 13 having the gate insulating film 16a between them.

An emitter electrode 26 has the surface electrode 23 and an buried electrode 25.

The surface electrode 23 is provided on the surface of the P-type base layer 13 and on the surface of the source layer 14 and is electrically connected to the P-type base layer 13 and the source layer 14.

The buried electrode 25 is provided at a position lower than the gate electrode 35 in the trench t. The buried electrode 25 is located at a position deeper than those of the P-type base layer 13 and the gate electrode 35.

The buried electrode 25 and the gate electrode 35 are made of a semiconductor material (polycrystalline silicon, for example) to which impurities are added and having conductivity. Alternatively, metal may be used as the buried electrode 25 and the gate electrode 35.

The gate electrode 35 and the buried electrode 25 are provided in one trench t. The insulating film 16 is provided between the buried electrode 25 and the gate electrode 35. The insulating film 16 is provided also between the gate electrode 35 and the surface electrode 23. The insulating film 16 is provided also between the side face of the buried electrode 25 and the side wall of the trench t, and between the buried electrode 25 and the bottom face of the trench t.

As illustrated in FIG. 7, a part 25a of the buried electrode 25 is led upward and connected to the surface electrode 23. The gate electrode 35 is not provided on a part of the trench t. In that portion, the part 25a of the surface electrode 25 extends in the depth direction in the trench t. As a result, the emitter potential to be given to the surface electrode 23 is also given to the buried electrode 25.

Also, a part of the gate electrode 35 is led upward and connected to a gate interconnect 60. The gate interconnect 60 is provided on the surface of the P-type base layer 13 separately from the surface electrode 23. The insulating film 65 intervenes between the surface electrode 23 and the gate interconnect 60.

In the embodiment, too, in a state in which a high potential is applied to the collector electrode 21 and a low potential to the emitter electrode 26 in a relative sense, when a desired gate potential is applied to the gate electrode 35, an inversion layer (channel) is formed in the vicinity of the boundary surface with the gate insulating film 16a in the P-type base layer 13. As a result, electrons are injected into the N-type base layer 12 from the source layer 14 through the channel, and the ON state is generated. At this time, moreover, holes are injected into the N-type base layer 12 from the collector layer 11, and resistance in the N-type base layer 12 is reduced.

In the embodiment, too, the buried electrode 25, which is a part of the emitter electrode 26 and to which the emitter potential is given is located at a position lower than the gate electrode 35 in the trench t. That is, a part of the emitter electrode 26 is located close to the collector electrode 21 side than the gate electrode 35.

Thus, the gate-collector capacity can be reduced, and controllability of the gate potential, that is, switching controllability is improved. Specifically, a drop in a switching speed caused by the gate-collector capacity can be suppressed. Also, current capacity of a gate driving circuit can be reduced.

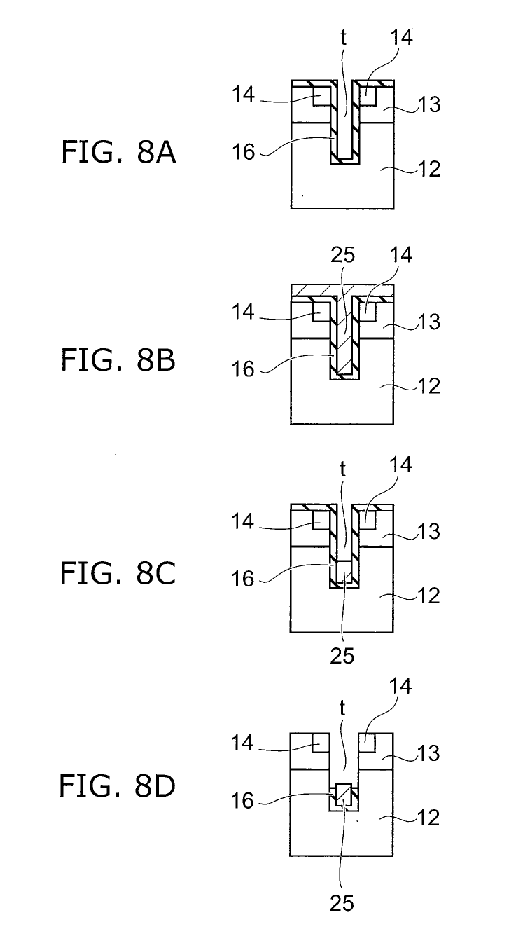

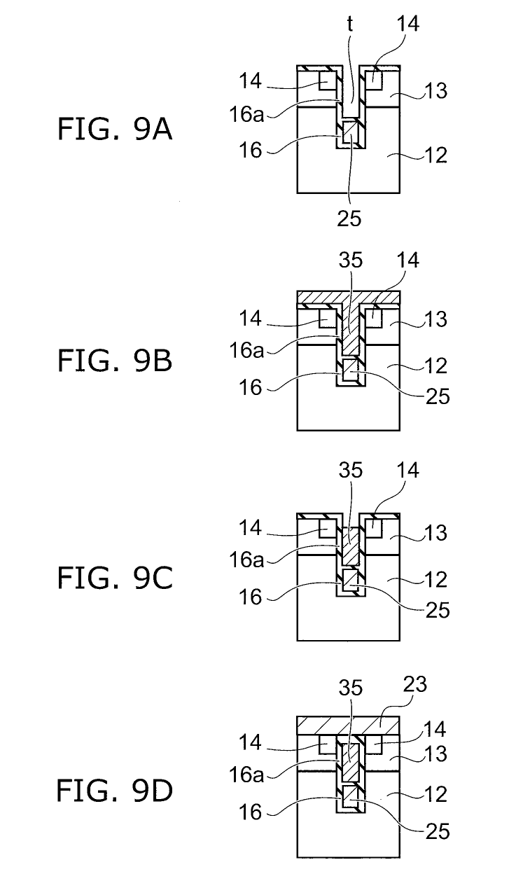

Subsequently, by referring to FIG. 8A to FIG. 9D, a manufacturing method of the semiconductor device of the embodiment will be described.

Until the trench t is formed, similarly to the embodiment, the processes in FIGS. 3A to 3D are proceeded with. Alternatively, the P-type base layer 13 and the source layer 14 may be formed after the trench t is formed.

After the trench t is formed, the insulating film 16 is formed on the bottom face and the side wall of the bottom part of the trench t (FIG. 8A), and the buried electrode 25 is embedded inside the insulating film 16 (FIG. 8B).

After that, the buried electrode 25 other than the bottom part of the trench t is removed (FIG. 8C), and moreover, the insulating film 16 on the buried electrode 25 is removed (FIG. 8D).

After that, the insulating film 16 is formed on the buried electrode 25, and moreover, the gate insulating film 16a is formed on the side wall of the trench t above the buried electrode 25 (FIG. 9A). Then, inside the gate insulating film 16a, the gate electrode 35 is buried (FIG. 9B).

The thicknesses of the insulating film 16 and the gate insulating film 16a may be equal or may be different. When the thickness of the gate insulating film 16a is smaller than that of the insulating film 16, MOS characteristics are improved. Also, when the thickness of the insulating film 16 is larger than that of the gate insulating film 16a, the gate capacity can be reduced.

After that, as illustrated in FIGS. 9C to 9D, the gate electrode material other than the trench t is removed, the insulating film on the surface of the source layer 14 and on the surface of the P-type base layer 13 is removed, and the insulating film 16 is formed on the gate electrode 35 in the trench t. Then, the surface electrode 23 of the emitter electrode is formed on the surface of the source layer 14 and on the surface of the P-type base layer 13.

In the embodiment, a process of forming another trench in the trench t is not necessary.

### Third Embodiment

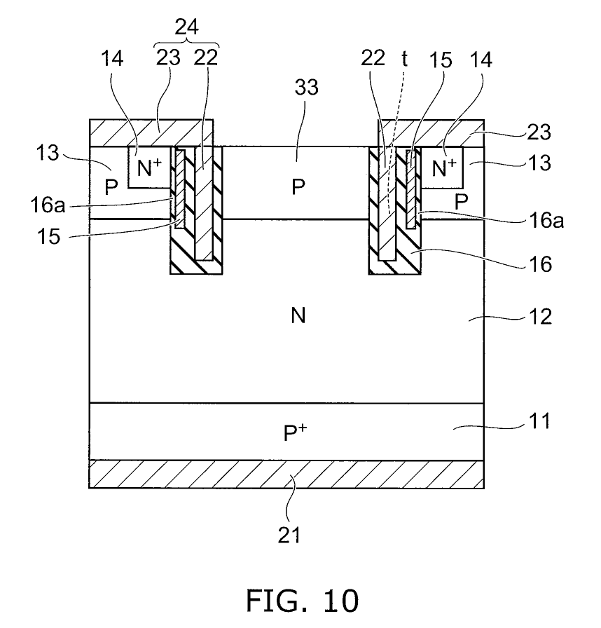

FIG. 10 is a schematic sectional diagram of a semiconductor device of a third embodiment.

The semiconductor layer of the embodiment includes the P⁺-type collector layer 11, the N-type base layer 12, the P-type base layer 13, the N⁺-type source layer 14, and a P-type semiconductor layer 33. The collector layer 11 has P-type impurity concentration higher than those of the P-type base layer 13 and the P-type semiconductor layer 33. The source layer 14 has N-type impurity concentration higher than that of the N-type base layer 12.

The N-type base layer 12 is provided on the collector layer 11. The P-type base layer 13 is provided on the N-type base layer 12. The P-type semiconductor layer 33 is also provided on the N-type base layer 12. The P-type base layer 13 and the P-type semiconductor layer 33 have substantially the same depth. The source layer 14 is selectively provided on the surface of the P-type base layer 13. The source layer 14 is not provided on the P-type semiconductor layer 33.

On the surface sides of those semiconductor layers, a plurality of the trenches t are formed. Each of the trenches t reaches the N-type base layer 12 from the surfaces of the P-type base layer 13 and the P-type semiconductor layer 33. The bottom part of the trench t is located in the N-type base layer 12. The trench t separates the P-type base layer 13 and the P-type semiconductor layer 33 from each other. On the N-type base layer 12, there are a region on which the P-type base layer 13 is provided between the adjacent trenches t and a region on which the P-type semiconductor layer 33 is provided between the adjacent trenches t.

The insulating film 16 is provided on the side walls and the bottom part of the trench t. Particularly, the insulating film formed on the side wall adjacent to the P-type base layer 13 in the trench t is referred to as the gate insulating film 16a.

The source layer 14 is adjacent to the side wall of the trench t. That is, the source layer 14 is adjacent to the gate insulating film 16a.

The gate electrode 15 is provided in the trench t. The gate electrode 15 is provided inside the gate insulating film 16a in the trench t. The bottom part of the gate electrode 15 is located at a position deeper than that of the P-type base layer 13 and is located in the vicinity of the boundary surface (PN-junction surface) between the P-type base layer 13 and the N-type base layer 12. The gate electrode 15 opposes the P-type base layer 13 through the gate insulating film 16a.

The emitter electrode 24 is provided on the surface of the P-type base layer 13 and on the surface of the source layer 14. The emitter electrode 24 is electrically connected to the source layer 14 and the P-type base layer 13. The emitter electrode 24 has the surface electrode 23 and the buried electrode 22.

The surface electrode 23 is provided on the surface of the P-type base layer 13 and on the surface of the source layer 14. The surface electrode 23 forms ohmic-contact with the surface of the source layer 14 and is electrically connected to the source layer 14. The surface in the P-type base layer 13 in contact with the surface electrode 23 has relatively high P-type impurity concentration and the surface electrode 23 forms ohmic-contact with the surface. Therefore, the P-type base layer 13 is also electrically connected to the surface electrode 23.

The surface electrode 23 is provided also on the trench t. In the trench t, the buried electrode 22 is provided below the surface electrode 23. The upper end portion of the buried electrode 22 continues to the surface electrode 23. The buried electrode 22 extends in the depth direction in the trench t from the surface electrode 23 to a position deeper than the gate electrode 15. The bottom part of the buried electrode 22 is located at a position deeper than the bottom parts of the P-type base layer 13 and the gate electrode 15.

The gate electrode 15 is provided between the source layer 14 and the buried electrode 22, and between the P-type base layer 13 and the buried electrode 22. The buried electrode 22 is provided between the gate electrode 15 and the P-type semiconductor layer 33.

The gate electrode 15 and the buried electrode 22 are provided in one trench t. The insulating film 16 is provided between the buried electrode 22 and the gate electrode 15. The insulating film 16 is also provided between the gate electrode 15 and the surface electrode 23. Moreover, the insulating film 16 is also provided below the gate electrode 15 and below the buried electrode 22 in the trench t.

The P-type semiconductor layer 33 is not connected to any of the electrodes and in an electrically floating state. Also, an N-type region is not formed in the P-type semiconductor layer 33.

In the embodiment, too, when a desired gate potential is applied to the gate electrode 15 in a state in which a high potential is applied to the collector electrode 21 and a low potential is applied to the emitter electrode 24 in a relative sense, an inversion layer (channel) is formed in the vicinity of the boundary surface with the gate insulating film 16a in the P-type base layer 13.

As a result, electrons are injected into the N-type base layer 12 from the source layer 14 through the channel, whereby the ON state is generated. At this time, moreover, the holes are injected into the N-type base layer 12 from the collector layer 11. The electrons injected into the N-type base layer 12 flow to the collector electrode 21 through the collector layer 11. The holes injected into the N-type base layer 12 flow to the surface electrode 23 through the P-type base layer 13.

In the embodiment, too, the buried electrode 22, which is a part of the emitter electrode 24 and to which the emitter potential is given, is located at a position lower than the gate electrode 15 in the trench t. That is, a part of the emitter electrode 24 is located closer to the collector electrode 21 side than the gate electrode 15. Moreover, by the buried electrode 22, the gate electrode 15 is shielded from the P-type semiconductor layer 33.

As a result, the gate-collector capacity can be reduced, and controllability of the gate potential, that is, switching controllability is improved. Specifically, a drop in a switching speed caused by the gate-collector capacity can be suppressed. Also, current capacity of a gate driving circuit can be reduced.

The P-type semiconductor layer 33 is not connected to the emitter electrode 24. Thus, the holes injected into the N-type base layer 12 flow to the surface electrode 23 of the emitter electrode 24 through the P-type base layer 13. Therefore, the holes do not flow into the P-type semiconductor layer 33. By forming such a region in which the holes do not flow, the holes are accumulated on a portion on the emitter side in the N-type base layer 12. The accumulation of the holes promotes injection of electrons into the N-type base layer 12. As a result, an ON voltage can be reduced.

The P-type semiconductor layer 33 is electrically floating. Thus, the potential of the P-type semiconductor layer 33 can fluctuate in conjunction with the collector potential. The potential fluctuation of the P-type semiconductor layer 33 may affect switching of the gate. For example, a negative capacity may be generated between the gate electrode 15 and the P-type semiconductor layer 33.

However, in the embodiment, by the buried electrode 22, the gate electrode 15 is shielded from the P-type semiconductor layer 33. As a result, the capacity between the gate and the collector can be reduced, and also, an influence of an unstable potential of the P-type semiconductor layer 33 on the gate electrode 15 can be suppressed. As a result, by providing the P-type semiconductor layer 33, a lower ON voltage can be realized while switching controllability is not damaged.

The P-type semiconductor layer 33 can be formed after the process illustrated in FIG. 3B. Alternatively, the P-type semiconductor layer 33 may be formed before the P-type base layer 13. The trench t may be formed before formation of the P-type base layer 13, the P-type semiconductor layer 33, and the source layer 14.

### Fourth Embodiment

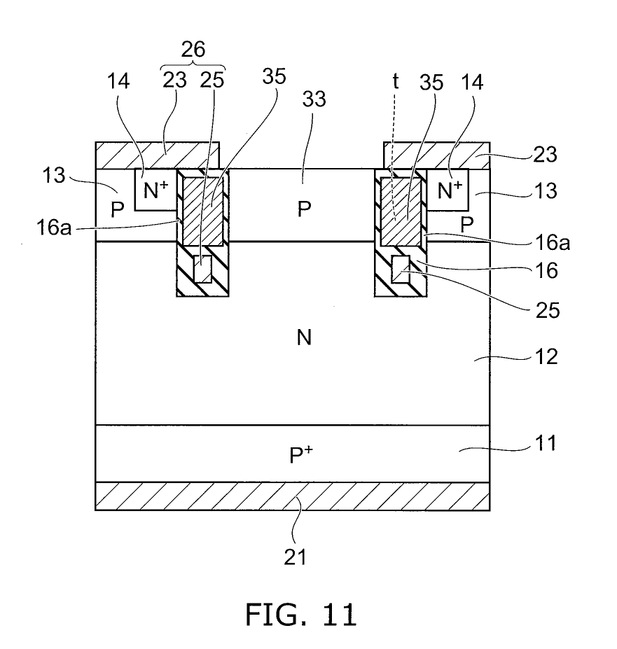

In the structure of the second embodiment described by referring to FIGS. 6 and 7, the P-type semiconductor layer 33 may be provided. This embodiment is illustrated in FIG. 11.

In the embodiment, too, there are a region in which the P-type base layer 13 is provided between the adjacent trenches t and a region in which the P-type semiconductor layer 33 is provided between the adjacent trenches t on the N-type base layer 12. The source layer 14 is provided on the surface of the P-type base layer 13.

In the embodiment, too, the buried electrode 25, which is a part of the emitter electrode 26 and to which the emitter potential is given, is located at a position lower than the gate electrode 35 in the trench t. As a result, the gate-collector capacity can be reduced, and controllability of the gate potential, that is, switching controllability is improved.

Also, by providing the P-type semiconductor layer 33 not connected to the emitter electrode 26, holes are accumulated in a portion on the emitter side in the N-type base layer 12. As a result, injection of electrons into the N-type base layer 12 is promoted, and the ON voltage can be reduced.

### Fifth Embodiment

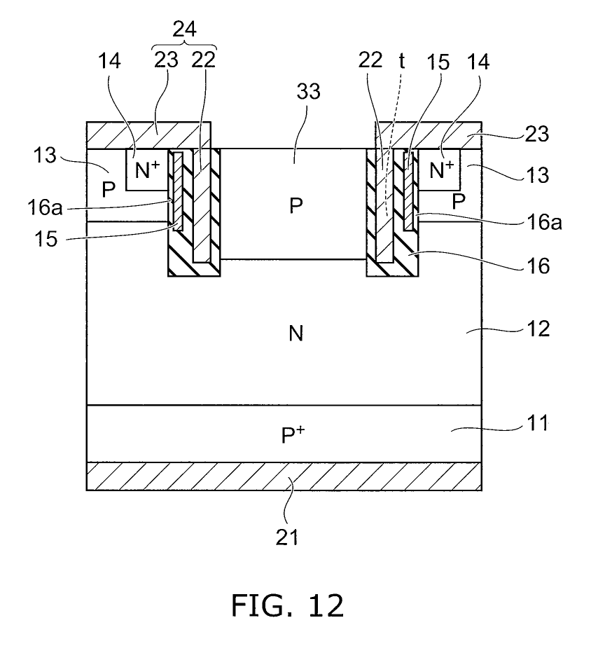

FIG. 12 is a schematic sectional diagram of a semiconductor device of the fifth embodiment. The semiconductor device of the embodiment has the same elements as those in the semiconductor device of the third embodiment illustrated in FIG. 10. However, in the embodiment, the P-type semiconductor layer 33 is provided deeper than the P-type base layer 13. That is, the P-type semiconductor layer 33 is made much closer to the bottom part of the trench t.

Since the P-type semiconductor layer 33 is provided close to the bottom part of the trench t, concentration of electric lines of force to the bottom part of the trench t can be alleviated. That is, concentration of electric field to the trench t bottom part is alleviated, and breakdown voltage is improved.

The structure of the embodiment may be applied to the fourth embodiment. That is, in the structure of the fourth embodiment illustrated in FIG. 11, the P-type semiconductor layer 33 may be positioned deeper than the P-type base layer 13.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a first conductivity type base layer;
a second conductivity type base layer provided on the first conductivity type base layer;
a gate insulating film provided on a side wall of each of a plurality of trenches which reach the first conductivity type base layer from a surface of the second conductivity type base layer;
a first conductivity type source layer selectively provided on the surface of the second conductivity type base layer adjacently to the gate insulating film;
a gate electrode provided inside of the gate insulating film in the trench; and
a main electrode provided on the surface of the second conductivity type base layer and on a surface of the first conductivity type source layer, provided at a position deeper than the gate electrode and the second conductivity type base layer in the trench, and electrically connected to the second conductivity type base layer and the first conductivity type source layer.

2. The device according to claim 1, wherein
the main electrode has:
a surface electrode provided on the surface of the second conductivity type base layer, on the surface of the first conductivity type source layer, and on the trench; and
a buried electrode which extends in the depth direction in the trench from the surface electrode on the trench to a position deeper than the gate electrode.

3. The device according to claim 2, wherein
a pair of the gate electrodes are provided in the one trench; and
the buried electrode is provided between the pair of gate electrodes.

4. The device according to claim 2, further comprising:
a second conductivity type semiconductor layer provided between the adjacent trenches on the first conductivity type base layer and in an electrically floating state.

5. The device according to claim 4, wherein
the gate electrode is provided between the first conductivity type source layer and the buried electrode; and
the buried electrode is provided between the gate electrode and the second conductivity type semiconductor layer.

6. The device according to claim 4, wherein
the second conductivity type semiconductor layer is located at a position deeper than the second conductivity type base layer.

7. The device according to claim 4, wherein
the trench separates the second conductivity type base layer and the second conductivity type semiconductor layer from each other.

8. The device according to claim 4, further comprising:
a collector electrode; and
a second conductivity type collector layer provided between the collector electrode and the first conductivity type base layer, wherein
the second conductivity type base layer and the second conductivity type semiconductor layer have second conductivity type impurity concentration lower than that of the collector layer.

9. The device according to claim 4, wherein
the second conductivity type semiconductor layer does not have a first conductivity type region provided.

10. The device according to claim 1, wherein
the main electrode has:
a surface electrode provided on the surface of the second conductivity type base layer and on the surface of the first conductivity type source layer; and
a buried electrode provided below the gate electrode in the trench through an insulating film.

11. The device according to claim 10, further comprising:
a second conductivity type semiconductor layer provided between the adjacent trenches on the first conductivity type base layer and in an electrically floating state.

12. The device according to claim 11, wherein
the second conductivity type semiconductor layer is located at a position deeper than the second conductivity type base layer.

13. The device according to claim 11, wherein
the trench separates the second conductivity type base layer and the second conductivity type semiconductor layer from each other.

14. The device according to claim 11, further comprising:
a collector electrode; and
a second conductivity type collector layer provided between the collector electrode and the first conductivity type base layer, wherein
the second conductivity type base layer and the second conductivity type semiconductor layer have second conductivity type impurity concentration lower than that of the collector layer.

15. The device according to claim 11, wherein
the second conductivity type semiconductor layer does not have a first conductivity type region provided.

16. The device according to claim 10, further comprising:
a second insulating film provided between the buried electrode and the first conductivity type base layer.

17. The device according to claim 1, further comprising:
a collector electrode; and
a second conductivity type collector layer provided between the collector electrode and the first conductivity type base layer.
